(19) United States
(12) Patent Application Publication
(10) Pub. No.: US 2025/0132230 A1
(43) Pub. Date: Apr. 24, 2025

(54) SEMICONDUCTOR DEVICE

(71) Applicant: Mitsubishi Electric Corporation, Tokyo (JP)

(72) Inventors: Tatsuya KAWASE, Tokyo (JP); Naoki YOSHIMATSU, Tokyo (JP); Kazuki YAMADA, Tokyo (JP); Arata IIZUKA, Tokyo (JP)

(73) Assignee: Mitsubishi Electric Corporation, Tokyo (JP)

(21) Appl. No.: 18/692,588

(22) PCT Filed: Nov. 22, 2021
(86) PCT No.: PCT/JP2021/042752

§ 371 Date: Mar. 15, 2024

(51) Int. Cl. H01L 23/49; H01L 23/00; H01L 23/31; H01L 23/538

(52) U.S. Cl. CPC H01L 23/49; H01L 23/3107; H01L 23/538; H01L 24/48; H01L 2224/48175

(57) ABSTRACT

The visibility of the inserted portions of the signal terminals after the insertion of the signal terminals into the lead frame is improved. A semiconductor device includes an insulating substrate, a semiconductor element, a main terminal frame, a signal terminal frame connected to the semiconductor element via a wire, and a sealing resin that seals a portion of the insulating substrate, the semiconductor element, a portion of the main terminal frame, and a portion of the signal terminal frame, in which the signal terminal frame includes a receiving portion in a portion exposed from the sealing resin, and the semiconductor device further comprising at least one signal terminal pin connected to the signal terminal frame via the receiving portion of the signal terminal frame so as to extend in a direction intersecting the upper surface of the insulating substrate.

### TECHNICAL FIELD

The present technique is a technique relates to a semiconductor device.

### BACKGROUND ART

For example, in order to reduce the size of a molded semiconductor device, in Patent Document 1, a technique is disclosed in which metal tubes are placed above a lead frame inside the mold, and corresponding signal terminals are inserted into the metal tube, thereby extracting signals from a semiconductor chip.

Also, in Patent Document 2, a configuration is disclosed in which holes are provided that pass through the mold and the lead frame, and corresponding signal terminals are inserted into the holes.

### PRIOR ART DOCUMENTS

### Patent Document(s)

[Patent Document 1] Japanese Patent Application Laid-Open No. 2010-129795

[Patent Document 2] Japanese Patent Application Laid-Open No. 2013-152966

### SUMMARY

### Problem to Be Solved by the Invention

In the molded semiconductor devices as described above, both the front and back surfaces of the lead frame are covered with a resin. Because of this, the inserted portions of the signal terminals cannot be visually confirmed after the insertion of the signal terminals, remaining a problem of difficulty in inspection.

The technique disclosed in the present specification has been made in view of the problem described above, and is a technique that improves the visibility of the inserted portions of the signal terminals after the insertion of the signal terminals into the lead frame.

### Means to Solve the Problem

A semiconductor device which is a first aspect of the technique disclosed in the present specification includes an insulating substrate having a circuit pattern on an upper surface thereof, a semiconductor element provided on the upper surface of the insulating substrate via the circuit pattern, a main terminal frame connected to the semiconductor element via a wire, a signal terminal frame connected to the semiconductor element via a wire, and a sealing resin that seals a portion of the insulating substrate, the semiconductor element, a portion of the main terminal frame, and a portion of the signal terminal frame, in which the signal terminal frame includes a receiving portion in a portion exposed from the sealing resin, and the semiconductor device further comprising at least one signal terminal pin connected to the signal terminal frame via the receiving portion of the signal terminal frame so as to extend in a direction intersecting the upper surface of the insulating substrate.

### Effects of the Invention

According to at least the first aspect of the technique disclosed in the present specification, the receiving portion of the signal terminal frame is provided in a portion exposed from the sealing resin; therefore, the visibility of the inserted portion after the insertion of the signal terminal pin into the signal terminal frame is improved.

The objects, characteristics, aspects, and advantages of the technique disclosed in the present specification will become more apparent from the following detailed description and the accompanying drawings.

### BRIEF DESCRIPTION OF DRAWINGS

FIG. 1 A cross-sectional view illustrating an example of a configuration of a semiconductor device according to Embodiment.

FIG. 2 A plan view illustrating the example of the configuration of the semiconductor device according to Embodiment,

FIG. 3 A diagram for comparing a conventional structure to a structure illustrated in Embodiment.

FIG. 4 A cross-sectional view illustrating an example of a configuration of a semiconductor device according to Embodiment.

FIG. 5 A diagram illustrating the example of the configuration of the semiconductor device according to Embodiment.

FIG. 6 A diagram illustrating a modification of a press-fit structure in the structure illustrated in FIG. 4.

FIG. 7 A cross-sectional view illustrating an example of a configuration of a semiconductor device according to Embodiment.

FIG. 8 A cross-sectional view illustrating an example of a configuration of a semiconductor device according to Embodiment.

FIG. 9 A plan view illustrating an example of a configuration of a semiconductor device according to Embodiment.

### DESCRIPTION OF EMBODIMENT(S)

Embodiment will be described below with reference to the accompanying drawings. In following Embodiments, although detailed features and the like are also illustrated for explaining the technique, they are mere examples, and not all of them are necessarily essential features to implement Embodiments.

It should be noted that the drawings are illustrated schematically, and for convenience of description, the configuration is to be omitted or the configuration is to be simplified as appropriate in the drawings. Also, the mutual relationship among sizes and positions in configurations and the like illustrated in separate drawings are not necessarily accurately drawn, and may be changed as appropriate. In addition, in the drawings such as plan views that are not cross-sectional views, hatching may be given to facilitate understanding of the contents of Embodiments.

In addition, in the following description, the same components are denoted by the same reference numerals, and the names and functions thereof are also similar. Accordingly, detailed descriptions thereof may be omitted to avoid redundancy.

Also, in the description to be made in the specification of the present specification, expressions that an X “is provided with”, “includes”, or “has” a component are not exclusive expressions that exclude the existence of other components unless otherwise specified.

Also, in the following description, even though ordinal numbers such as “first”, and “second” may be used, these terms are for promoting the understanding of the contents of Embodiments and are not for defining the order caused by such ordinal numbers.

Also, in the description to be made in the present specification, even though terms indicating specific positions or directions such as “upper”, “lower”, “left”, “right”, “side”, “bottom”, “front”, and “back” may be used, these terms are for promoting the understanding of the contents of Embodiments and are not related to the positions or directions at the time of implementation of Embodiments.

### Embodiment 1

Hereinafter, a semiconductor device according to Embodiment 1 will be described.

### Configuration of Semiconductor Device

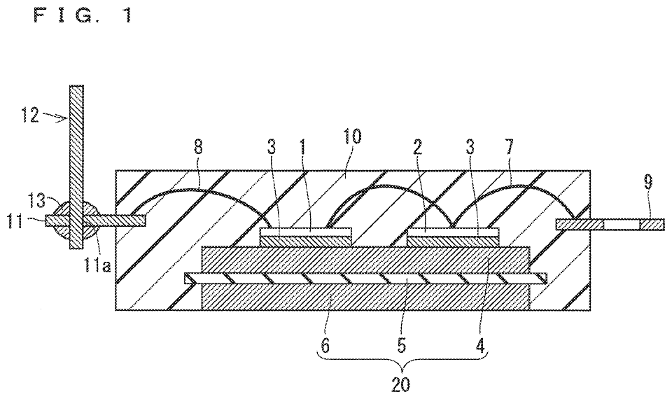

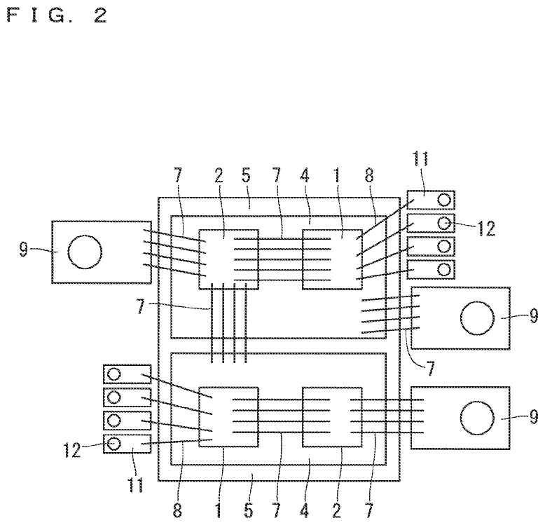

FIG. 1 is a cross-sectional view illustrating an example of a configuration of a semiconductor device according to Embodiment 1. Also, FIG. 2 is a plan view illustrating the example of the configuration of the semiconductor device according to Embodiment 1. Note that in FIG. 2, illustration of the sealing resin is omitted for simplicity.

As the example is illustrated in FIGS. 1 and 2, semiconductor elements 1 and semiconductor elements 2 are mounted onto front circuit patterns 4 via a bonding material 3, respectively. The front circuit patterns 4 are arranged on the upper surface of an insulating material 5. Further, on the lower surface of the insulating material 5 is provided with a back surface circuit pattern 6. Note that the front circuit patterns 4, the insulating material 5, and the back surface circuit pattern 6 are also collectively referred to as an insulating substrate 20.

Main current wiring wires 7 connect the semiconductor elements 1, the semiconductor elements 2, the front circuit patterns 4, and main terminal frames 9 to form an electric circuit. Signal terminal wires 8 connect the semiconductor elements 1 and signal terminal frames 11.

A sealing resin 10 seals the semiconductor elements 1, the semiconductor elements 2, the bonding material 3, the front circuit patterns 4, the insulating material 5, the back surface circuit pattern 6, the main current wiring wires 7, the signal terminal wires 8, the main terminal frames 9, and the signal terminal frames 11. However, the sealing resin 10 seals with the lower surface (back surface) of the back surface circuit pattern 6, portions of the main terminal frames 9, and portions of the signal terminal frames 11 being exposed to the outside of the sealing resin 10.

A signal terminal frame hole 11a is formed in a portion of the signal terminal frame 11 exposed from the scaling resin 10. A signal terminal pin 12 is inserted into the signal terminal frame hole 11a. A conductive bonding material 13 is arranged to cover the periphery of the signal terminal frame hole 11a, and connects the signal terminal frame 11 and the signal terminal pin 12 inserted into the signal terminal frame hole 11a. At this point, the signal terminal pin 12 is fixed so as to extend in a direction intersecting the upper surface of the insulating substrate 20.

Also, FIG. 2 is a plan view illustrating the example of the configuration of the semiconductor device according to Embodiment 1. Note that in FIG. 2, illustration of the sealing resin is omitted for simplicity.

The semiconductor element 1 is an insulated gate bipolar transistor (i.e., IGBT), a metal-oxide-semiconductor field-effect transistor (i.e., MOSFET), or the like. And the semiconductor element 2 is a diode or the like. As the material of semiconductor element 1 and the semiconductor element 2, for example, Si, SiC, GaN, or the like are assumed.

The element size of the semiconductor element 1 and the semiconductor element 2 is preferably approximately 5 mm or more and 15 mm or less, taking improvement in yield or mountability thereof into account. Also, while in Embodiment 1, a case is illustrated in which the semiconductor element 1 is an IGBT made of Si and the semiconductor element 2 is a diode made of Si, a configuration consisting a reverse conducting IGBT (i.e. RC-IGBT) in which an IGBT and a diode are integrated, or a SiC MOSFET alone without a diode may also be adopted.

The bonding material 3 is preferably a material with high electrical conductivity and high thermal conductivity, and is composed of, for example, solder or an Ag sinter material. The thickness of the bonding material 3 is preferably approximately 50 μm or more and 100 μm or less because the thinner the bonding material 3 is, the higher the thermal property is.

The front circuit pattern 4 is composed of metal, such as aluminum, an aluminum alloy, copper, or a copper alloy. The front circuit pattern 4 is arranged directly below the semiconductor element 1 and the semiconductor element 2, and has a function of diffusing the heat from the semiconductor element 1 and the heat from the semiconductor element 2. Therefore, it is desirable for the front circuit pattern 4 to have a thickness sufficient for thorough heat diffusion in the plane direction of the front circuit pattern 4. The thickness of the front circuit pattern 4 is preferably, for example, 0.4 mm or more and 1.2 mm or less. Also, it is desirable that the front circuit pattern 4 is provided with irregularities such as dimples or slits for improving the adhesion with the sealing resin 10.

The insulating material 5 is composed of an insulating resin, ceramics, or the like. The main component of the insulating resin is, for example, epoxy resin. Ceramics consist of main components such as Al₂O₃, Si₃N₄, AlN, and the like.

While the insulating material 5 is preferably thin since it is also required to have the heat dissipation property, a reduction in thickness thereof decreases its dielectric strength. For this reason, the thickness of the insulating material is preferably approximately 100 μm or more and 350 μm or less.

The back surface circuit pattern 6 is composed of metal or the like. The metal is composed of, for example, aluminum, an aluminum alloy, copper, a copper alloy or the like.

The main current wiring wire 7 is a wire or the like composed of aluminum, an aluminum alloy, copper, or a copper alloy. Also, the main current wiring wire 7 may be composed of a material in which aluminum and copper are combined, for example, a composite material in which the outer periphery is composed of aluminum and the inside is composed of copper.

Although it depends on the assumed current capacity, it is desirable that the diameter of the main current wiring wire 7 is, for example, Φ200 μm or more and Φ1000 μm or less. Also, the shape of the main current wiring wire 7 may have a ribbon-like shape with an expanded width to increase the current capacity thereof. Alternatively, in order to increase the current capacity, a structure such as direct lead bonding (DLB) may be adopted in which the main terminal frame 9 is extended to the upper surface of the semiconductor element 1 and the upper surface of the semiconductor element 2 to directly bonded the two to each other.

A signal terminal wire 8 is a wire or the like composed of aluminum, an aluminum alloy, copper, or a copper alloy. Unlike the main current wiring wire 7, the signal terminal wire 8 does not need to carry a large current. Therefore, it is desirable that the diameter of the main current wiring wire 7 is Φ100 μm or more and Φ400 μm or less, for example.

The main terminal frame 9 is composed of copper, a copper alloy or the like. The main terminal frame 9 may be composed of aluminum, an aluminum alloy or the like for weight reduction. Although it depends on the specification current or the main terminal width, it is desirable that the thickness of the main terminal frame 9 is, for example, 0.5 mm or more and 2.0 mm or less to suppress self-heating of the main terminal frames 9 when current is applied.

The scaling resin 10 is composed of epoxy resin or the like. In order to suppress peeling between the sealing resin 10 and the front circuit patterns 4, it is desirable that the linear thermal expansion coefficient of the sealing resin 10 is 18 ppm/° C. or more and 24 ppm/° C. or less, for example.

Further, the temperature of the sealing resin 10 increases due to self-heating of the semiconductor elements 1 and the semiconductor elements 2 when energized. It is desirable that the glass transition temperature Tg of the sealing resin 10 is 175° C. or higher so that the linear thermal expansion coefficient of the sealing resin 10 does not change due to the temperature increase.

The signal terminal frame 11 is composed of copper, a copper alloy or the like. And, the signal terminal frame 9 may be composed of aluminum, an aluminum alloy or the like for weight reduction. Similar to the signal terminal wire 8, the signal terminal frame 11 also does not need to carry a large current. Therefore, it is sufficient for the thickness of the signal terminal frame 11 to be, for example, 0.5 mm or more and 1.0 mm or less.

The signal terminal frame hole 11a is formed in the signal terminal frame 11. The shape of the signal terminal frame hole 11a may be circular or square. The size increases in the planar direction with the size of the signal terminal frame hole 11a being too large, whereas the slidability with the signal terminal pin 12 deteriorates with the same being too small. Therefore, it is desirable that the size of the signal terminal frame hole 11a is Φ0.5 mm or more and Φ3.0 mm or less, for example.

The signal terminal pin 12 is composed of copper, a copper alloy or the like. And, the signal terminal pin 12 may be composed of aluminum, an aluminum alloy or the like for weight reduction. Also, the shape or specifications of the end portion of the signal terminal pin 12 opposite to the end portion inserted into the signal terminal frame hole 11a may be changed depending on the application.

For example, when a press-fit is required as a method of connecting the signal terminal pin 12 to an external connection substrate (control substrate), a press-fit shape can be provided at the corresponding location of the signal terminal pin 12. In this case, the signal terminal pin 12 preferably has the spring property, and the material of the signal terminal pin 12 is preferably phosphor bronze or the like.

Also, when soldering is required as a method of connecting the signal terminal pin 12 to an external connection substrate, the signal terminal pin 12 may have a straight shape and the front surface may be coated with Ni plating or Sn plating for solderable.

The conductive bonding material 13 is composed of a solder material, a conductive paste (adhesive) material, or the like. The flowing current is a signal current and the current value is low; therefore, a conductive paste material is sufficient as the conductive bonding material 13.

Adopting the signal terminal pin 12 and the signal terminal frame 11 being separate members allows, while the signal terminal frame 11 to be common, the shape of the signal terminal pin 12 (for example, diameter, length, shape compatible with press fit, and the like) to be arbitrarily changed. Therefore, development in a wide variety of products is ensured.

In addition, this allows the signal terminal frame 11 to be reduced in size in plan view (shrinking); therefore, the number of pieces that can be produced from a frame of the same size (manufacturable quantity) increases compared to the conventional structure, leading to improving productivity.

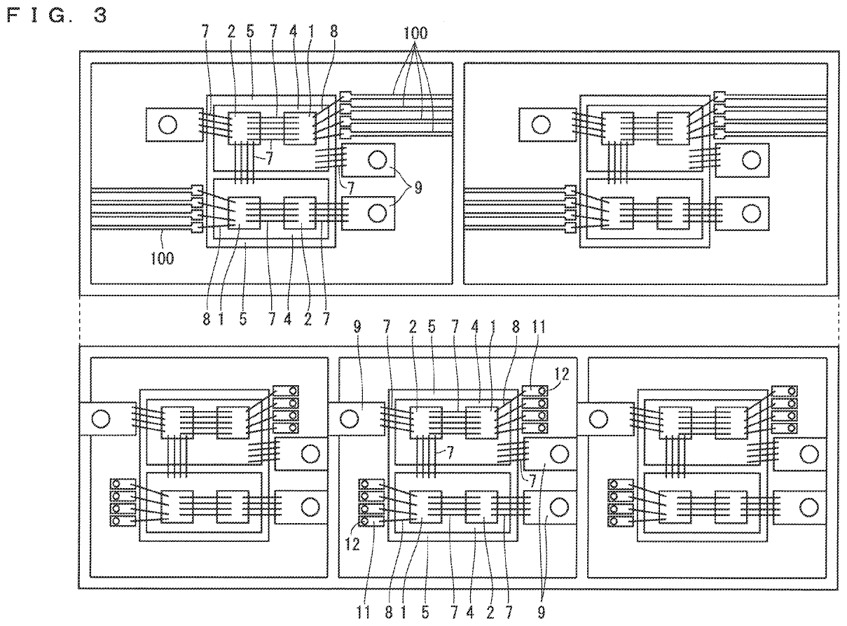

FIG. 3 is a diagram for comparing a conventional structure to a structure illustrated in Embodiment 1. As an example is illustrated in FIG. 3, signal terminal pins 100 in the conventional structure (the upper diagram in FIG. 3) corresponds to the portion configured by the signal terminal pins 12 and the signal terminal frames 11 in the structure illustrated in Embodiment 1 (the lower diagram in FIG. 3).

According to FIG. 3, it can be seen that, since the signal terminal frames 11 are reduced in size, the number of semiconductor devices manufactured from a frame of the same size increases compared to the conventional structure.

Further, with one side of the signal terminal frames 11 is exposed, the connection between the signal terminal pins 12 and the signal terminal frames 11 can be visually confirmed with ease. Therefore, inspection performance improves, leading to improving module manufacturability.

### Embodiment 2

A semiconductor device according to Embodiment 2 will be described. In the following description, components similar to the components described in above Embodiment will be illustrated with the same reference numerals, and detailed description thereof will be omitted as appropriate.

### Configuration of Semiconductor Device

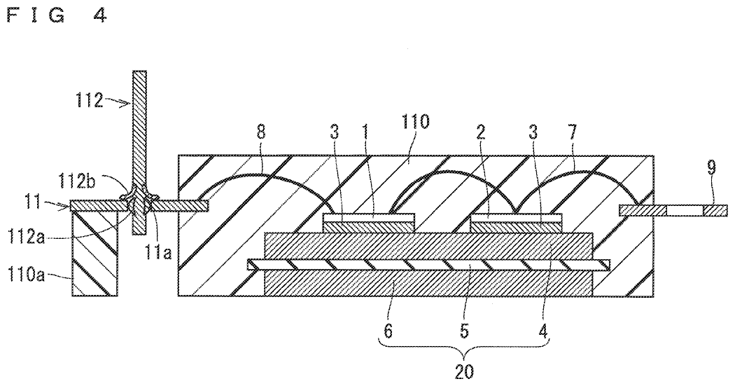

FIG. 4 is a cross-sectional view illustrating an example of a configuration of a semiconductor device according to Embodiment 2.

A signal terminal pin 112 includes a press-fit structure 112a that corresponds to the signal terminal frame hole 11a of the signal terminal frame 11. The signal terminal pin 112 is connected to the signal terminal frame 11 via the press-fit structure 112a inserted into the signal terminal frame hole 11a. At this point, the signal terminal pin 112 is fixed so as to extend in a direction intersecting the upper surface of the insulating substrate 20. Also, the signal terminal pin 112 includes a flap portion 112b that contacts the surface of the signal terminal frame 11. The flap portion 112b contacts a portion of the signal terminal frame 11 exposed from a sealing resin 110 that does not correspond to the signal terminal frame hole 11a (a portion surrounding the signal terminal frame hole 11a in plan view). The flap portion 112b may be composed of a plurality of flap pieces, or may be composed of a single flap that surrounds around like a skirt.

Further, a signal terminal frame receiving portion 110a is formed on the lower surface side (back surface side) of the signal terminal frame 11 as a part of the sealing resin 110. It is preferable that the signal terminal frame receiving portion 110a has a shape in which a space is provided only directly below the signal terminal frame hole 11a of the signal terminal frame 11 (that is, the signal terminal frame receiving portion 110a is formed in the periphery of the signal terminal frame hole 11a in plan view). A cylindrical shape or a square prism shape may be conceivable to adopt for the shape of the space formed directly below the signal terminal frame hole 11a, for example.

It is desirable that the space formed directly below the signal terminal frame hole 11a of the signal terminal frame 11 be provided in a manner that the insertion of the signal terminal pin 112 is not blocked by the signal terminal frame receiving portion 110a.

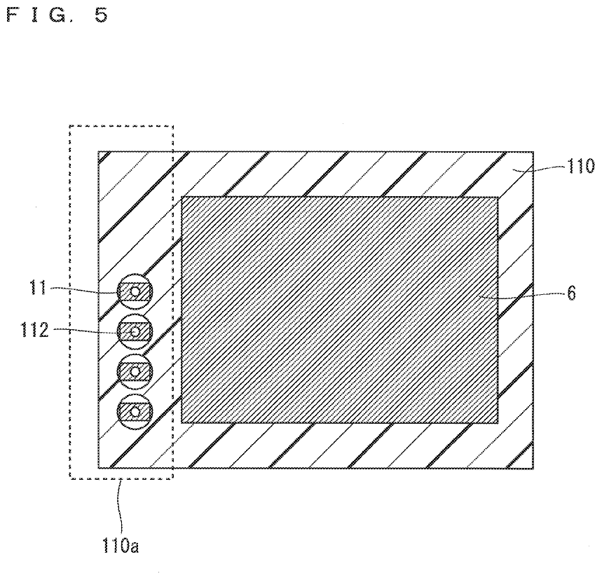

FIG. 5 is a diagram illustrating the example of the configuration of the semiconductor device according to Embodiment 2. Note that FIG. 5 is a diagram seen from the bottom side of the semiconductor device, that is, the side where the back surface circuit pattern 6 is exposed.

As an example is illustrated in FIG. 5, the signal terminal frame receiving portion 110a is formed so as to avoid being directly below the signal terminal frame holes 11a of the signal terminal frames 11.

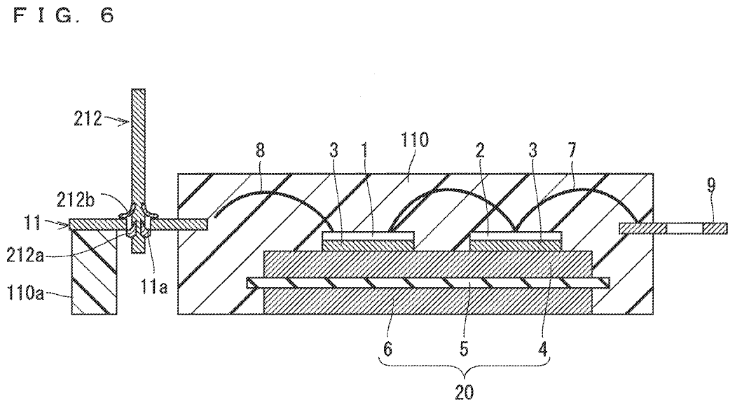

Further, FIG. 6 is a diagram illustrating a modification of a press-fit structure in the structure illustrated in FIG. 4.

As illustrated in FIG. 6, a signal terminal pin 212 includes a press-fit structure 212a that corresponds to the signal terminal frame hole 11a of the signal terminal frame 11. Also, the signal terminal pin 212 includes a flap portion 212b that contacts the surface of the signal terminal frame 11. The flap portion 212b may be composed of a plurality of flap pieces, or may be composed of a single flap that surrounds around like a skirt.

The press-fit structure 212a is a structure having a projection for sandwiching the signal terminal frame 11 together with the flap portion 212b. For example, the structure having a projection indicates a shape in which the width thereof (in FIG. 6, the width in the radial direction of the signal terminal frame hole 11a) increases as it extends in the inserting direction of the signal terminal pin 212 (vertically downward direction in FIG. 6).

Adopting a hole and press-fit structure for the contact structure between the signal terminal frame 11 and the signal terminal pin 112 (or the signal terminal pin 212) requires no bonding material or the like for the connection, improving productivity.

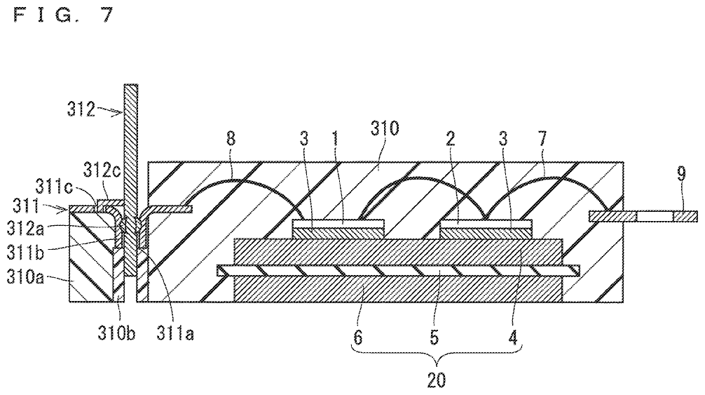

Further, by providing the flap portion 112b (or the flap portion 212b), the contact area between the signal terminal frame 11 and the signal terminal pin 112 (or the signal terminal pin 212) increases, stabilizing the conductivity between the signal terminal pin 112 (or the signal terminal pin 212) and the signal terminal frame 11. Note that the flap portion 112b (or the flap portion 212b) is also applied to FIG. 7, which will be described later.

In this case, the surface of the signal terminal frame 11 needs to be exposed to some extent from the sealing resin 110 in order to bring the flap portion 112b (or the flap portion 212b) into contact with the signal terminal frame 11.

Further, by providing the signal terminal frame receiving portions 110a in the sealing resin 110, the rigidity in the thickness direction around the positions where the signal terminal pins 112 (or the signal terminal pins 212) of the signal terminal frames 11 are inserted is increased, this improves the vibration resistance in the thickness direction when the signal terminal pins 112 (or the signal terminal pins 212) are inserted or after the signal terminal pins 112 (or the signal terminal pins 212) are inserted, stabilizing the quality.

Also, by forming the press-fit structure 212a with a projection, displacement of the signal terminal pins 212 in the thickness direction or pulling out of the signal terminal frames 11 after the signal terminal pins 212 are inserted is suppressed, stabilizing the quality.

Further, by sandwiching the signal terminal frame 11 between the press-fit structure 212a and the flap portion 212b, the contact area between the signal terminal pin 212 and the signal terminal frame 11 increases, stabilizing the conductivity.

### Embodiment 3

A semiconductor device according to Embodiment 3 will be described. In the following description, components similar to the components described in above Embodiments will be illustrated with the same reference numerals, and detailed description thereof will be omitted as appropriate.

### Configuration of Semiconductor Device

FIG. 7 is a cross-sectional view illustrating an example of a configuration of a semiconductor device according to Embodiment 3.

A signal terminal frame hole 311a is formed in a signal terminal frame 311. A signal terminal pin 312 is inserted into the signal terminal frame hole 311a. At this point, the signal terminal pin 312 is fixed so as to extend in a direction intersecting the upper surface of the insulating substrate 20. Further, the signal terminal frame 311 includes a burring portion 311b formed at a location where the signal terminal pin 312 is inserted. The burring portion 311b is a portion formed in the process of forming the signal terminal frame hole 311a by burring, and is formed to have the periphery of the signal terminal frame hole 311a concave. The straight portion of the burring portion 311b (that is, the portion that is recessed toward the signal terminal frame hole 311a and extends vertically downward) is desirably about 5 mm or less in consideration of workability and the like.

The signal terminal pin 312 includes a press-fit structure 312a that corresponds to the signal terminal frame hole 311a of the signal terminal frame 311. Also, the signal terminal pin 312 includes a positioning pin 312c for preventing rotation. Despite its small size, the positioning pin 312c for preventing rotation functions satisfactorily. Hence, it is sufficient that the size of the positioning pin 312c for preventing rotation and the size of a positioning hole corresponding to the positioning pin 312c are as much as 3 mm or less. A positioning hole 311c corresponding to the positioning pin 312e is formed in the signal terminal frame 311.

Further, a signal terminal frame receiving portion 310a is formed on the back surface side of the signal terminal frame 311 as a part of the sealing resin 310. It is preferable that the signal terminal frame receiving portion 310a has a shape in which a space is provided only directly below the signal terminal frame hole 311a of the signal terminal frame 311. A cylindrical shape or a square prism shape may be conceivable to adopt for the shape of the space formed directly below the signal terminal frame hole 311a, for example.

Also, the sealing resin 310 includes a positioning portion 310b that aligns the positions of the signal terminal pins 312. It is sufficient that the length of the positioning portion 310b is as much as 10 mm or less which is the length long enough to align the signal terminal pin 312.

The signal terminal frame 311 including the burring portion 311b allows the alignment of the signal terminal pins 312. Further, the contact area between the signal terminal pin 312 and the signal terminal frame 311 increases through the burring portion 311b, thereby stabilizing conductivity. Note that the burring portion 311b is also applicable to FIGS. 4, 5, and 6.

Further, the positioning pin 312c of the signal terminal pin 312 and the positioning hole 311c of the signal terminal frame 311 enable positioning of the signal terminal pin 312 in the rotational direction. Therefore, manufacturability is improved. Note that the positioning pin 312c and the positioning hole 311c are also applicable to FIGS. 4, 5, and 6.

Further, by providing the positioning portion 310b of the sealing resin 310 on the lower surface (back surface) of the signal terminal frame 311, the manufacturability when inserting the signal terminal pin 312 is improved. Note that the positioning portion 310b is also applicable to FIGS. 4, 5, and 6.

Further, after the signal terminal pin 312 is inserted, the signal terminal pin 312 is fixed by the burring portion 311b and the positioning portion 310b, so that the vibration resistance of the signal terminal pin 312 in the planar direction is improved.

### Embodiment 4

A semiconductor device according to Embodiment 4 will be described. In the following description, components similar to the components described in above Embodiments will be illustrated with the same reference numerals, and detailed description thereof will be omitted as appropriate.

### Configuration of Semiconductor Device

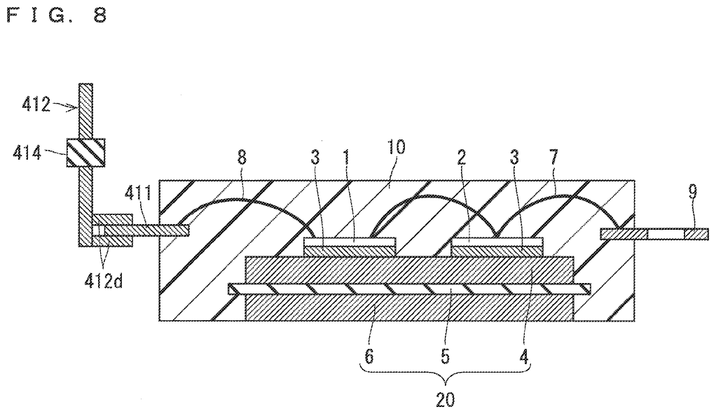

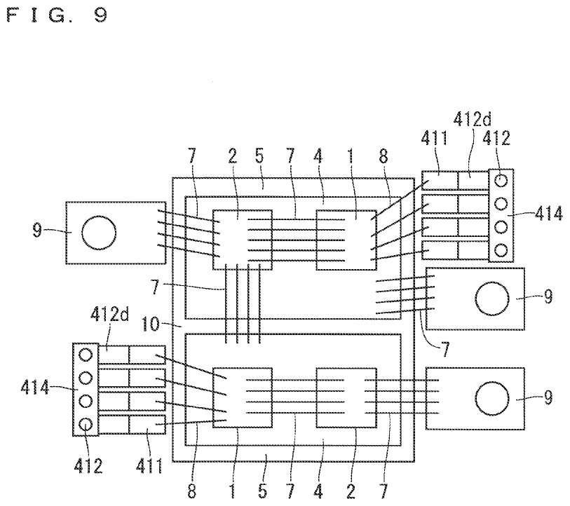

FIG. 8 is a cross-sectional view illustrating an example of a configuration of a semiconductor device according to Embodiment 4. Also, FIG. 9 is a plan view illustrating the example of the configuration of the semiconductor device according to Embodiment 1. Note that in FIG. 9, illustration of the sealing resin is omitted for simplicity.

A signal terminal frame 411 has a portion thereof exposed from the sealing resin 10. A signal terminal pin 412 includes a caulking structure 412d for the signal terminal frame 411. As a caulking structure, a structure in which the signal terminal frame 411 is simply sandwiched in the thickness direction, or another structure capable of holding the signal terminal frame 411 may be adoptable.

Also, the signal terminal frame 411 may include a signal terminal pin mutual fixing member 414. The signal terminal pin mutual fixing member 414 can fix the mutual positions of the plurality of signal terminal pins 412, As the material of the signal terminal pin mutual fixing member 414, insulating resin or the like is assumed, for example. Note that the signal terminal pin mutual fixing member 414 is also applicable to FIGS. 4, 5, and 6.

By having the caulking structure 412d, the signal terminal pin 412 can sandwich the end portion of the signal terminal frame 411 exposed from the sealing resin 10. After that, further, in a caulking process, both can be sandwiched from above and below and pressure bonded together. At this point, the signal terminal pin 412 is fixed so as to extend in a direction intersecting the upper surface of the insulating substrate 20, According to such a configuration, stable contact with the signal terminal pin 412 can be implemented on the upper and lower surfaces of the signal terminal frame 411, stabilizing the conductivity.

Also, the mutual positions of the signal terminal pins 412 are stabilized by the signal terminal pin mutual fixing member 414. Thereby, improving the accuracy of alignment between the signal terminal pin 412 and the signal terminal frame 411, and improving productivity.

In addition, plurality of signal terminal pins 412 can be connected in a state where mutual positions thereof are fixed by the signal terminal pin mutual fixing member 414; that enables positioning of the respective signal terminal pins 412 and eliminating the need to perform a caulking process, improving productivity.

### Effects Produced by Embodiments Described Above

Next, an example of the effects produced by the above Embodiments will be described. In the following description, although the effects are described based on the specific configuration described in above Embodiments, to the extent that the same effects are produced, such a specific configuration may be replaced with another specific configuration described in the present specification. In other words, for convenience, only one of the specific configurations that are associated may be described below as a representative, however, the specific configuration described as a representative may be replaced with another specific configuration to which it is associated.

Further, the replacement may be made across a plurality of Embodiments. That is, a case in which similar effects are produced by combining respective configurations whose examples are described in different Embodiments may be adoptable.

According to Embodiments described above, the semiconductor device includes the insulating substrate 20, the semiconductor element 1 (or the semiconductor 2), the main terminal frame 9, the signal terminal frame 11 (or the signal terminal frame 311, the signal terminal frame 411), and the sealing resin 10 (or the sealing resin 110, the sealing resin 310). The insulating substrate 20 has a circuit pattern on the upper surface thereof. Here, the circuit pattern corresponds to, for example, the front circuit pattern 4. The semiconductor element 1 (or the semiconductor element 2) is provided on the upper surface of the insulating substrate 20 via the front circuit pattern 4. The main terminal frame 9 is connected to the semiconductor element 1 (or the semiconductor element 2) via a wire. Here, the wire corresponds to, for example, at least one of the main current wiring wire 7 and the signal terminal wire 8. The signal terminal frame 11 is connected to the semiconductor element 1 via the signal terminal wire 8. The sealing resin 10 seals a portion of the insulating substrate 20, the semiconductor element 1, the semiconductor element 2, a portion of the main terminal frame 9, and a portion of the signal terminal frame 11. Also, the signal terminal frame 11 includes a receiving portion in a portion exposed from the sealing resin 10. Here, the receiving portion corresponds to at least one of the signal terminal frame hole 11a, the signal terminal frame hole 311a, the signal terminal frame hole 311a, the burring portion 311b, and the end portion of the signal terminal frame 411, for example. The semiconductor device includes at least one signal terminal pin 12 (or the signal terminal pin 112, the signal terminal pin 212, the signal terminal pin 312, the signal terminal pin 412). The signal terminal pin 12 is connected to the signal terminal frame 11 via the signal terminal frame hole 11a of the signal terminal frame 11 so as to extend in a direction intersecting the upper surface of the insulating substrate 20.

According to such a configuration, the signal terminal frame hole 11a of the signal terminal frame 11 is provided in a portion exposed from the sealing resin 10; therefore, the visibility of the inserted portion after the insertion of the signal terminal pin 12 into the signal terminal frame 11 is improved. Further, adopting the signal terminal pin 12 and the signal terminal frame 11 being separate members allows the shape of the signal terminal pin 12 to be arbitrarily changed. In addition, this allows the signal terminal frame 11 to be reduced in size in plan view (shrinking); therefore, the number of pieces that can be produced from a frame of the same size (manufacturable quantity) increases compared to the conventional structure, leading to improving productivity.

In addition, when the configurations other than the configurations described in the present specification are appropriately added to the configuration described above, that is, even if even if a configuration that has not been described as a configuration described above in the present specification is appropriately added, similar effects can be produced.

Further, according to Embodiments described above, the receiving portion is the signal terminal frame hole 11a formed in the signal terminal frame 11. And, with being inserted in the signal terminal frame hole 11a, the signal terminal pin 12 is connected to the signal terminal frame 11 using a conductive bonding material. According to such a configuration, the signal terminal pin 12 and the signal terminal frame 11 can be connected with a simple configuration, so that manufacturability (easiness of manufacture and degree of reduction in manufacturing cost) is improved.

Further, according to Embodiments described above, the receiving portion is the signal terminal frame hole 11a (or the signal terminal frame hole 311a) formed in the signal terminal frame 11 (or the signal terminal frame 311). And, the signal terminal pin 112 (or the signal terminal pin 212, the signal terminal pin 312) includes the press-fit structure 112a (or the press-fit structure 212a, the press-fit structure 312a) at the position corresponding to the signal terminal frame hole 11a (or the signal terminal frame hole 311a). The signal terminal pin 112 is connected to the signal terminal frame 11 via the press-fit structure 112a. According to such a configuration, the signal terminal pin 12 and the signal terminal frame 11 can be connected without using a bonding material, so that manufacturability (easiness of manufacture and degree of reduction in manufacturing cost) is improved.

Further, according to Embodiments described above, the press-fit structure 212a has a shape in which the width thereof increases as it extends in the inserting direction. According to such a configuration, the press-fit structure 212a has a caulking structure, displacement of the signal terminal pin 212 due to vibration in the insertion direction after the insertion of the signal terminal pin 212 is suppressed. Therefore, reliability of the product is improved.

Further, according to Embodiments described above, the receiving portion is the signal terminal frame hole 311a formed in the signal terminal frame 311. The signal terminal frame hole 311a is formed to have a periphery concave. According to such a configuration, the contact area between the signal terminal pin 312 and the signal terminal frame 311 in the vertical direction can be increased by the burring portion 311b formed in the periphery of the signal terminal frame hole 311a, so that the stability in electrical contact can be obtained.

Further, according to Embodiments described above, the contact structure is provided in which the signal terminal pin 112 (or the signal terminal pin 212) contacts the portion that does not correspond to the signal terminal frame hole 11a in the portion of the signal terminal frame 11 exposed from the sealing resin 110. Here, the contact structure corresponds to, for example, the flap portion 112b or the flap portion 212b. According to such a configuration, the contact area between the signal terminal pin 112 and the signal terminal frame 11 can be secured by the flap portion 112b, stabilizing electrical conduction between the two.

Further, according to Embodiments described above, the signal terminal frame receiving portion 110a (or the signal terminal frame receiving portion 310a) of the sealing resin 110 (or the sealing resin) covers the lower surface of the signal terminal frame 11 (or signal terminal frame 311) in the periphery of the signal terminal frame hole 11a (or the signal terminal frame hole 311a). According to such a configuration, by covering one side of the signal terminal frame 11 with the signal terminal frame receiving portion 110a of the sealing resin 110, the rigidity of the signal terminal frame 11 is improved. Therefore, the displacement of the signal terminal pin 112 due to vibration in the insertion direction can be suppressed, thereby reliability of the product is improved.

Further, according to Embodiments described above, the sealing resin 310 includes the positioning portion 310b for positioning the signal terminal pin 312 in the periphery of the signal terminal frame hole 311a. According to such a configuration, the signal terminal pin 312 is positioned by the positioning portion 310b in the sealing resin 310, so that the positional accuracy regarding insertion of the signal terminal pin 312 is improved.

Further, according to Embodiments described above, the signal terminal pin 312 includes the positioning pin 312e for positioning. Further, the signal terminal frame 311 includes the positioning hole 311c into which the positioning pin 312c is inserted. According to such a configuration, by providing the positioning pin 312c and the corresponding positioning hole 311c, positioning of the signal terminal pin 312 in the rotational direction is enabled when inserting the signal terminal pin 312.

Further, according to Embodiments described above, the signal terminal pin 412 includes the caulking structure 412d for sandwiching the receiving portion of the signal terminal frame 411. Here, the receiving portion of the signal terminal frame 411 includes, for example, the end portion of the signal terminal frame 411 that is sandwiched by the caulking structure 412d. According to such a configuration, the signal terminal pin 412 and the signal terminal frame 411 are connected through the caulking structure, so that the bonding strength between the signal terminal pin 412 and the signal terminal frame 411 is improved, and reliability is improved.

Further, according to Embodiments described above, a plurality of signal terminal pins 412 are provided. And, the semiconductor device includes a fixing member that fixes the arrangement between the plurality of signal terminal pins 412. Here, the fixing member corresponds to, for example, the signal terminal pin mutual fixing member 414. According to such a configuration, the accuracy of mutual arrangement is improved by fixing and integrating the signal terminal pins 412 in advance. Further, the process of bonding the signal terminal pins 412 and the signal terminal frames 411 can be performed collectively, improving productivity.

### Modification in Embodiments Described Above

Although in Embodiments described above, the qualities of materials of, materials of, dimensions of, shapes of, relative arrangement relationships, or conditions of implementation of each component may also be described, they are illustrative in all aspects and are not limitative.

Accordingly, it is understood that numerous other modifications, variations, and equivalents can be devised without departing from the scope of the invention. For example, a case where modifying at least one component, a case where adding or omitting components, and further, a case where extracting at least one component in at least one Embodiment and combining it with a component of another Embodiment are included.

Further, in above-described Embodiments, when a material name or the like is described without being specified, the material contains other additives, for example, an alloy or the like, so far as consistent with Embodiments.

Further, “one or more” components may be included when described that “one” component is provided in Embodiments described above, so far as consistent with Embodiments.

Furthermore, each component in Embodiments described above is a conceptual unit, and within the scope of the technology disclosed in the present specification, a case where one component is composed of a plurality of structures, a case where one component corresponds to a part of a structure, and further, a case where a plurality of components are provided in one structure are included.

Further, each component in Embodiments described above includes a structure having another structure or shape as long as the same function is exhibited.

Also, the descriptions in the present specification are referred for the every object related to the technique, and none of them are regarded as conventional techniques.

### EXPLANATION OF REFERENCE SIGNS

1 semiconductor element, 2 semiconductor element, 3 bonding material, 9 main terminal frame, 10 sealing resin, 11 signal terminal frame, 12 signal terminal pin, 13 conductive bonding material, 20 insulating substrate, 100 signal terminal pin, 110 sealing resin, 112 signal terminal pin, 112a press-fit structure, 212 signal terminal pin, 212a press-fit structure, 310 sealing resin, 310b positioning portion, 311 signal terminal frame, 311c positioning hole, 312 signal terminal pin, 312a press-fit structure, 312c positioning pin, 411 signal terminal frame, 412 signal terminal pin, 412d caulking structure.

1. A semiconductor device comprising:
an insulating substrate having a circuit pattern on an upper surface thereof;
a semiconductor element provided on the upper surface of the insulating substrate via the circuit pattern;
a main terminal frame connected to the semiconductor element via a wire;
a signal terminal frame connected to the semiconductor element via a wire; and
a sealing resin that seals a portion of the insulating substrate, the semiconductor element, a portion of the main terminal frame, and a portion of the signal terminal frame, wherein
the signal terminal frame includes a receiving portion in a portion exposed from the sealing resin, and
the semiconductor device further comprising at least one signal terminal pin connected to the signal terminal frame via the receiving portion of the signal terminal frame so as to extend in a direction intersecting the upper surface of the insulating substrate.

2. The semiconductor device according to claim 1, wherein
the receiving portion is a hole formed in the signal terminal frame, and,
with being inserted in the hole, the signal terminal pin is connected to the signal terminal frame using a conductive bonding material.

3. The semiconductor device according to claim 1, wherein
the receiving portion is a hole formed in the signal terminal frame,
the signal terminal pin further includes a press-fit structure at a position corresponding to the hole, and
the signal terminal pin is connected to the signal terminal frame via the press-fit structure.

4. The semiconductor device according to claim 3, wherein
the press-fit structure has a shape in which a width thereof increases as it extends in an inserting direction.

5. The semiconductor device according to claim 1, wherein
the receiving portion is a hole formed in the signal terminal frame, and
the hole is formed to have a periphery concave.

6. The semiconductor device according to claim 1, further comprising
a contact structure provided in which the signal terminal pin contacts a portion that does not correspond to the receiving portion in a portion of the signal terminal frame exposed from the sealing resin.

7. The semiconductor device according to claim 1, wherein
the sealing resin covers a lower surface of the signal terminal frame at the periphery of the receiving portion.

8. The semiconductor device according to claim 7, wherein
the sealing resin further includes a positioning portion for positioning the signal terminal pin in the periphery of the receiving portion.

9. The semiconductor device according to claim 1, wherein
the signal terminal pin further includes a positioning pin for positioning, and
the signal terminal frame further includes a positioning hole into which the positioning pin is inserted.

10. The semiconductor device according to claim 1, wherein
the signal terminal pin further includes a caulking structure for sandwiching the receiving portion of the signal terminal frame.

11. The semiconductor device according to claim 1, further comprising:
a plurality of the signal terminal pins; and
a fixing member that fixes an arrangement between the plurality of signal terminal pins.
